(19) United States
(12) Patent Application Publication
(10) Pub. No.: US 2021/0287971 A1
(43) Pub. Date: Sep. 16, 2021

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Takuma HARA, Kanazawa Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/009,994

(22) Filed: Sep. 2, 2020

(30) Foreign Application Priority Data
Mar. 16, 2020 (JP) 2020-045485

(51) Int. Cl. H01L 23/495; H01L 29/423

(52) U.S. Cl. CPC H01L 23/49562; H01L 29/42364; H01L 23/49517

(57) ABSTRACT

A semiconductor device includes first and second metallic members, and a semiconductor chip provided on the first metallic member that includes a first electrode, a first semiconductor region of a first conductive type, second semiconductor regions of a second conductive type, third semiconductor regions of the first conductive type, gate electrodes, and a second electrode. The gate electrodes face the second semiconductor regions via ¥ gate insulating layers. The second electrode is electrically connected to the plurality of second semiconductor regions and the plurality of third semiconductor regions. The second metallic member is provided on the semiconductor chip. The semiconductor chip includes a first portion located between the metallic members as viewed in a first direction and a second portion. A thickness of each of the gate insulating layers in the second portion is larger than that of the gate insulating layers in the first portion.

### CROSS-REFERENCE TO RELATED APPLICATION(S)

This application is based upon and claims the benefit of priority from Japanese Patent Application No. 2020-045485, filed Mar. 16, 2020, the entire contents of which are incorporated herein by reference.

### FIELD

Embodiments described herein relate generally to a semiconductor device.

### BACKGROUND

Semiconductor devices such as metal-oxide-semiconductor field-effect transistors (MOSFETs), insulated-gate bipolar transistors (IGBTs), and reverse-conducting IGBTs (RC-IGBTs) are used for the purpose of, for example, power conversion. It is desirable that semiconductor devices be unlikely to have breakage occurring therein.

### DESCRIPTION OF THE DRAWINGS

FIG. 1 is a plan view illustrating a semiconductor device according to at least one embodiment.

FIG. 2 is a sectional view taken along line II-II illustrated in FIG. 1.

FIG. 3 is a sectional view taken along line III-III illustrated in FIG. 1.

FIG. 4 is a plan view illustrating the semiconductor device according to at least one embodiment.

FIG. 5 is a sectional view taken along line V-V illustrated in FIG. 4.

FIGS. 6A and 6B are sectional views illustrating respective portions illustrated in FIG. 5 in an enlarged manner.

FIG. 7 is a graph representing a relationship between the thickness of a gate insulating layer and a threshold value of voltage of a gate electrode.

FIG. 8 is a sectional view taken along line VIII-VIII illustrated in FIG. 4.

FIGS. 9A and 9B are sectional views illustrating respective portions of a semiconductor device according to a modification example of at least one embodiment.

FIGS. 10A and 10B are sectional views illustrating respective portions of a semiconductor device according to a modification example of at least one embodiment.

FIG. 11 is a sectional view illustrating a portion of a semiconductor device according to a modification example of at least one embodiment.

FIG. 12 is a sectional view illustrating a portion of a semiconductor device according to a modification example of at least one embodiment.

FIGS. 13A and 13B are sectional views illustrating respective portions of a semiconductor device according to a modification example of at least one embodiment.

FIG. 14 is a sectional view illustrating a portion of a semiconductor device according to a modification example of at least one embodiment.

### DETAILED DESCRIPTION

At least one embodiment provides a semiconductor device capable of reducing the probability of breakage occurring therein.

In general, according to at least one embodiment, a semiconductor device includes a first metallic member, a semiconductor chip, and a second metallic member. A first terminal is electrically connected to the first metallic member. The semiconductor chip is provided on the first metallic member. The semiconductor chip includes a first electrode, a first semiconductor region of a first conductive type, a plurality of second semiconductor regions of a second conductive type, a plurality of third semiconductor regions of the first conductive type, a plurality of gate electrodes, and a second electrode. The first semiconductor region is provided on the first electrode. The plurality of second semiconductor regions is provided on the first semiconductor region. The plurality of third semiconductor regions is respectively provided on the plurality of second semiconductor regions. The plurality of gate electrodes respectively faces the plurality of second semiconductor regions via a plurality of gate insulating layers. The second electrode is electrically connected to the plurality of second semiconductor regions and the plurality of third semiconductor regions. The second metallic member is provided on the semiconductor chip, and a second terminal is electrically connected to the second metallic member. The semiconductor chip includes a first portion located between the first metallic member and the second metallic member as viewed in a first direction leading from the first metallic member toward the second metallic member and a second portion located side by side with the first portion as viewed in a direction perpendicular to the first direction. A thickness of each of the gate insulating layers in the second portion is larger than a thickness of each of the gate insulating layers in the first portion.

Hereinafter, embodiments will be described with reference to the drawings.

The drawings are merely schematic or conceptual ones, and, for example, a relationship between thickness and width of each portion and a ratio between sizes of respective portions are not necessarily the same as the actual or real ones. Even when the same portion is illustrated, the relative dimension or ratio thereof may be illustrated in different manners depending on the drawings.

In the present specification and each drawing, elements similar to those previously described therein are assigned the respective same reference characters and the detailed description thereof is omitted as appropriate.

In the following description and drawings, the notes “n+”, “n”, “n⁻”, “p⁺”, and “p” represent the relative highness and lowness of each impurity concentration. More specifically, a notation with “+” suffixed thereto indicates that the impurity concentration is relatively higher than that represented by a notation with neither of “+” and “−” suffixed thereto, and a notation with “−” suffixed thereto indicates that the impurity concentration is relatively lower than that represented by a notation with neither of “+” and “−” suffixed thereto. In a case where both a p-type impurity and an n-type impurity are contained in each of the respective regions, these notations represent the relative highness and lowness of a net impurity concentration obtained after such impurities compensate for each other.

In each embodiment to be described in the following description, a p-type semiconductor region and an n-type semiconductor region may be replaced by each other in implementing each embodiment.

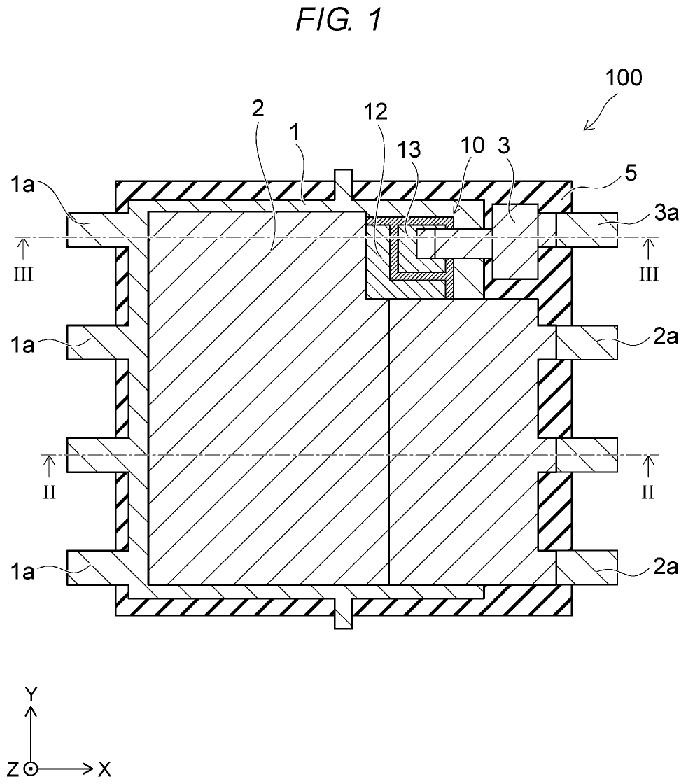

FIG. 1 is a plan view illustrating a semiconductor device according to at least one embodiment.

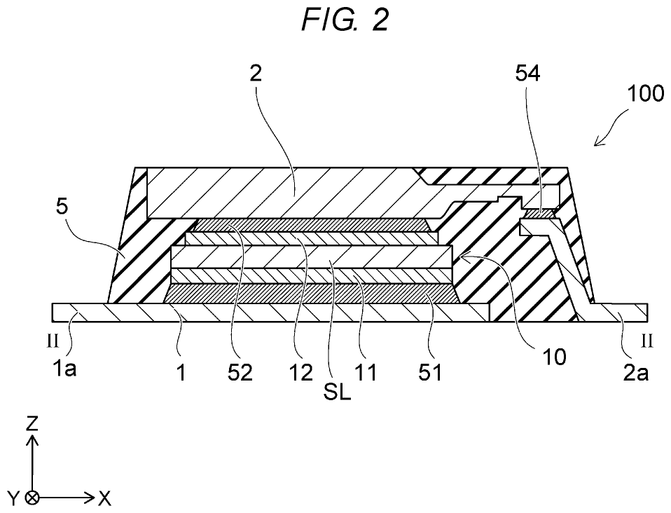

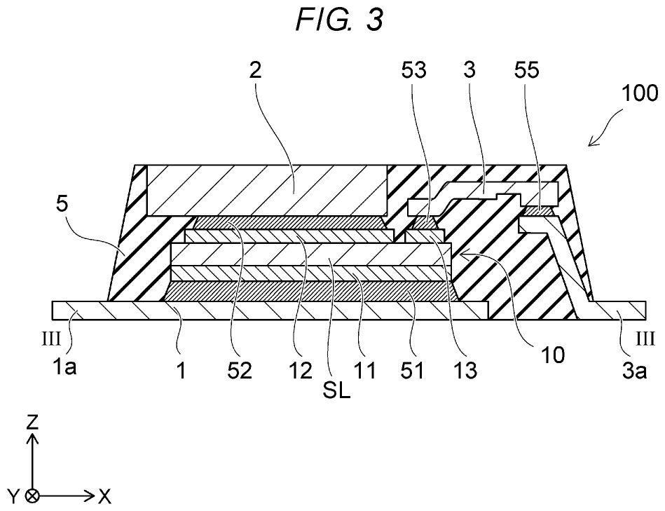

FIG. 2 is a sectional view taken along line II-II illustrated in FIG. 1. FIG. 3 is a sectional view taken along line illustrated in FIG. 1.

As illustrated in FIG. 1 to FIG. 3, the semiconductor device 100 includes a first metallic member 1, a second metallic member 2, a third metallic member 3, a sealing portion 5, and a semiconductor chip 10. Furthermore, in FIG. 1, a part of the sealing portion 5 is omitted from illustration.

In the description of each embodiment, an XYZ orthogonal coordinate system is used. A direction leading from the first metallic member 1 toward the second metallic member 2 is assumed to be the “Z-direction (first direction)”. Two directions which are perpendicular to the Z-direction and are mutually orthogonal are respectively assumed to be the “X-direction (second direction)” and the “Y-direction (third direction)”. Moreover, for the sake of explanation, a direction leading from the first metallic member 1 toward the second metallic member 2 is referred to as “up”, and the opposite direction is referred to as “down”. These directions are based on a relative positional relationship between the first metallic member 1 and the second metallic member 2 and are independent of the direction of gravitational force.

The first metallic member 1 is provided as a lower surface of the semiconductor device 100. A first terminal 1a is electrically connected to the first metallic member 1. For example, the first terminal 1a is formed integrally with the first metallic member 1. The first metallic member 1 and the first terminal 1a may be configured with mutually different materials. For example, as illustrated in FIG. 1, the first terminal 1a includes a plurality of first terminals 1a as viewed in the Y-direction, and each first terminal 1a extends along the X-direction.

The semiconductor chip 10 is provided on the first metallic member 1. The semiconductor chip 10 is, for example, a MOSFET. The semiconductor chip 10 may be an IGBT or an RC-IGBT. The semiconductor chip 10 includes a first electrode 11, a semiconductor layer SL, a second electrode 12, and a third electrode 13, as illustrated in FIG. 2 and FIG. 3.

The first electrode 11 is provided on the first metallic member 1, and is electrically connected to the first metallic member 1. The semiconductor layer SL is provided on the first electrode 11. The second electrode 12 and the third electrode 13 are provided on the semiconductor layer SL. The third electrode 13 is disposed away from the second electrode 12, and is electrically isolated from the second electrode 12.

The second metallic member 2 is provided on a part of the semiconductor chip 10, and is electrically connected to the second electrode 12. A second terminal 2a is electrically connected to the second metallic member 2. For example, as illustrated in FIG. 1, the second terminal 2a includes a plurality of second terminals 2a as viewed in the Y-direction, and each second terminal 2a extends along the X-direction.

The third metallic member 3 is provided on another part of the semiconductor chip 10, and is electrically connected to the third electrode 13. A third terminal 3a is electrically connected to the third metallic member 3.

The thickness of each of the first metallic member 1, the second metallic member 2, and the third metallic member 3 along the Z-direction is larger than the thickness of each of the first electrode 11, the second electrode 12, and the third electrode 13 along the Z-direction.

In an example illustrated in FIG. 2 and FIG. 3, the first electrode 11 is electrically connected to the first metallic member 1 via a connection portion 51. The second metallic member 2 is electrically connected to the second electrode 12 via a connection portion 52. The third metallic member 3 is electrically connected to the third electrode 13 via a connection portion 53. The second metallic member 2 is electrically connected to the second terminal 2a via a connection portion 54. The third metallic member 3 is electrically connected to the third terminal 3a via a connection portion 55. At least one embodiment is not limited to this example, and one member may be in pressure contact with the other member without via a connection portion. Alternatively, the second metallic member 2 may be formed integrally with the second terminal 2a. The third metallic member 3 may be formed integrally with the third terminal 3a.

The shape of each of the first metallic member 1, the second metallic member 2, and the third metallic member 3 is not limited to the illustrated example, and may be changed as appropriate according to the use or application of the semiconductor device 100. Moreover, the numbers of terminals included in each of and the shape of each of the first terminal 1a, the second terminal 2a, and the third terminal 3a can also be changed as appropriate.

The sealing portion 5 covers the upper surface and side surfaces of the first metallic member 1 and the lower surface and side surfaces of the second metallic member 2 and also covers the third metallic member 3 and the semiconductor chip 10. Apart of each of the first terminal 1a, the second terminal 2a, and the third terminal 3a is not covered with the sealing portion 5 and is exposed on the outside of the semiconductor device 100.

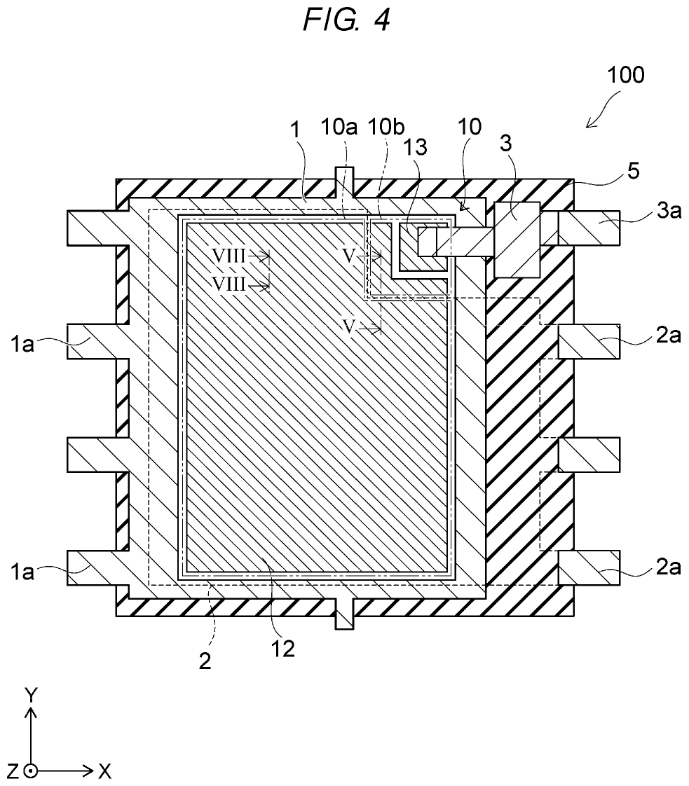

FIG. 4 is a plan view illustrating the semiconductor device according to at least one embodiment.

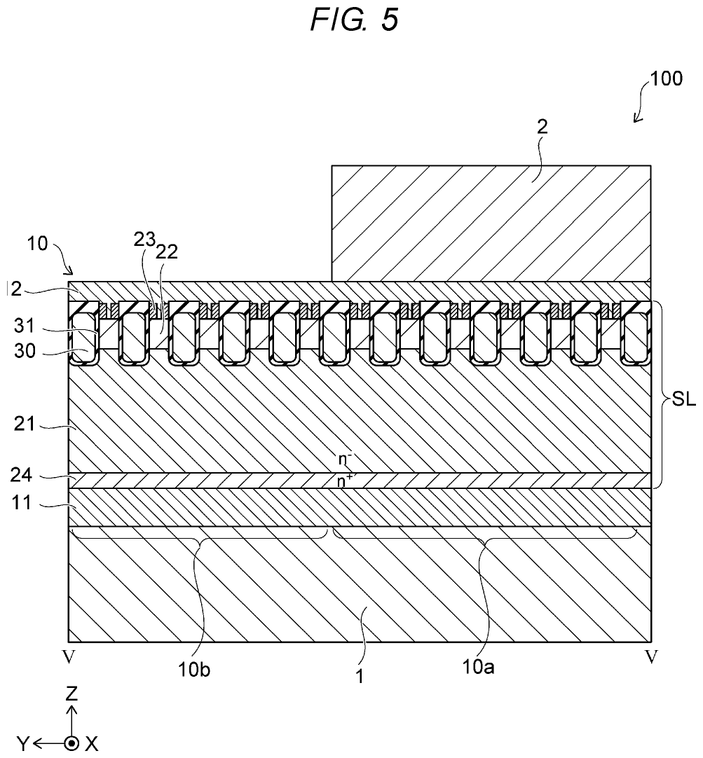

FIG. 5 is a sectional view taken along line V-V illustrated in FIG. 4.

In FIG. 4, the second metallic member 2 is illustrated with a dashed line. As illustrated in FIG. 4, the semiconductor chip 10 includes a first portion 10a and a second portion 10b. The first portion 10a is located between the first metallic member 1 and the second metallic member 2 as viewed in the Z-direction. The second portion 10b is located side by side with the first portion 10a as viewed in a direction perpendicular to the Z-direction. In the illustrated example, the second portion 10b is located side by side with a part of the first portion 10a as viewed in the X-direction and is located side by side with another part of the first portion 10a as viewed in the Y-direction. The second portion 10b is not located between the first metallic member 1 and the second metallic member 2 as viewed in the Z-direction.

As illustrated in FIG. 5, the semiconductor layer SL includes an n⁻ type (i.e., a first conductive type) semiconductor region 21 (i.e., a first semiconductor region), a p type (i.e., a second conductive type) semiconductor region (i.e., a second semiconductor region), an n⁺ type semiconductor region 23 (i.e., a third semiconductor region), an n⁺ type semiconductor region 24, and a gate electrode 30. In this example, the semiconductor chip 10 is a MOSFET. The n⁺ type semiconductor region 24 is provided on the first electrode 11, and is electrically connected to the first electrode 11. The n⁻ type semiconductor region 21 is provided on the n⁺ type semiconductor region 24. The n⁻ type semiconductor region 21 is electrically connected to the first electrode 11 via the n⁺ type semiconductor region 24.

A plurality of p type semiconductor regions 22 is provided on the n⁻ type semiconductor region 21. A plurality of n⁺ type semiconductor regions 23 is respectively provided on the plurality of p type semiconductor regions 22. The plurality of p type semiconductor regions 22 respectively faces a plurality of gate electrodes 30 via a plurality of gate insulating layers 31. In the illustrated example, the gate electrode 30 faces the p type semiconductor region 22 as viewed in the Y-direction.

The first electrode 11, the n⁻ type semiconductor region 21, the plurality of p type semiconductor regions 22, the plurality of n⁺ type semiconductor regions 23, the n⁺ type semiconductor region 24, and the plurality of gate electrodes 30 are provided in both the first portion 10a and the second portion 10b. The second electrode 12 is provided in a part of the second portion 10b and the first portion 10a, and is electrically connected to the plurality of p type semiconductor regions 22 and the plurality of n⁺ type semiconductor regions 23. The third electrode 13 is provided in another part of the second portion 10b, and is electrically connected to the plurality of gate electrodes 30.

In the second portion 10b, the n⁺ type semiconductor region 23 and the gate electrode 30 may be provided so as to be not below the third electrode 13 but only below the second electrode 12. Alternatively, in the second portion 10b, the n⁺ type semiconductor region 23 and the gate electrode 30 may be provided below the second electrode 12 and the third electrode 13.

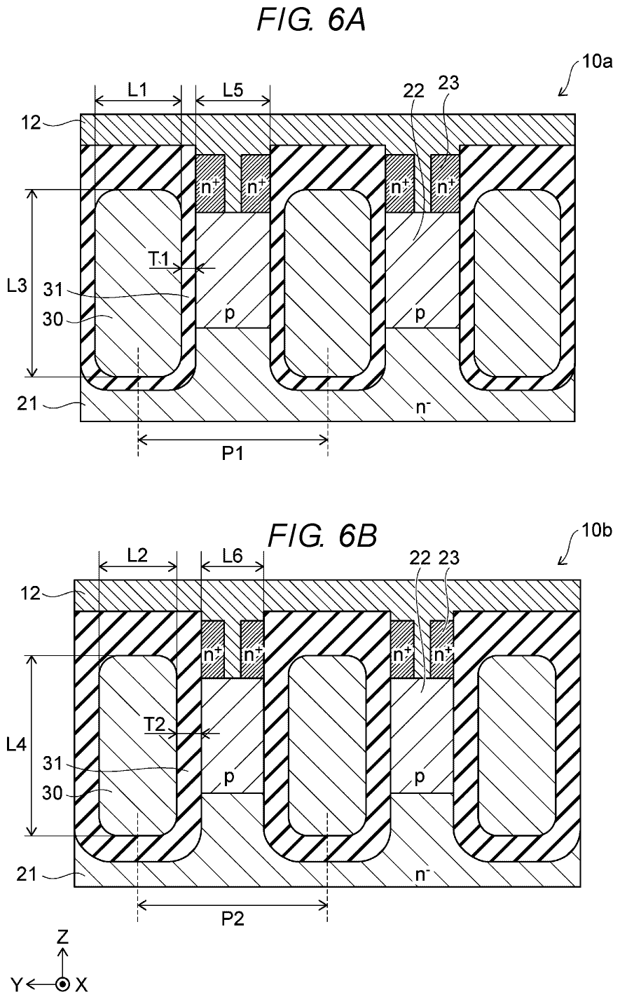

FIGS. 6A and 6B are sectional views illustrating respective portions illustrated in FIG. 5 in an enlarged manner. FIG. 6A illustrates a part of the first portion 10a. FIG. 6B illustrates a part of the second portion 10b.

As illustrated in FIGS. 6A and 6B, the thickness T2 of the gate insulating layer 31 in the second portion 10b is larger than the thickness T1 of the gate insulating layer 31 in the first portion 10a. The thickness T1 corresponds to the length of the gate insulating layer 31 between the p type semiconductor region 22 and the gate electrode 30 along the Y-direction in the first portion 10a. The thickness T2 corresponds to the length of the gate insulating layer 31 between the p type semiconductor region 22 and the gate electrode 30 along the Y-direction in the second portion 10b.

For example, the length L2 of the gate electrode 30 along the Y-direction in the second portion 10b is smaller than the length L1 of the gate electrode 30 along the Y-direction in the first portion 10a. The length L4 of the gate electrode 30 along the Z-direction in the second portion 10b is smaller than the length L3 of the gate electrode 30 along the Z-direction in the first portion 10a. The length L6 of the p type semiconductor region 22 along the Y-direction in the second portion 10b is smaller than the length L5 of the p type semiconductor region 22 along the Y-direction in the first portion 10a. The pitch P1 of the plurality of gate electrodes 30 in the first portion 10a is equal to the pitch P2 of the plurality of gate electrodes 30 in the second portion 10b. The pitch P1 corresponds to a distance between the center of one gate electrode 30 along the Y-direction and the center of another gate electrode 30 adjacent to the one gate electrode 30 along the Y-direction in the first portion 10a. The pitch P2 corresponds to a distance between the center of one gate electrode 30 along the Y-direction and the center of another gate electrode 30 adjacent to the one gate electrode 30 along the Y-direction in the second portion 10b.

An operation of the semiconductor device 100 is described.

With a positive voltage being applied to the first electrode 11 with respect to the second electrode 12, a voltage higher than or equal to a threshold value is applied to the gate electrodes 30 via the third electrode 13. With this application of the voltage, a channel (i.e., an inversion layer) is formed in each p type semiconductor region 22, so that the semiconductor chip 10 enters an on-state. Electrons flow from the second electrode 12 to the first electrode 11 through the channel. In other words, an electric current flows from the first electrode 11 to the second electrode 12. Afterwards, when the voltage being applied to the gate electrodes 30 becomes lower than the threshold value, the channel in each p type semiconductor region 22 disappears, so that the semiconductor chip 10 enters an off-state.

An example of the material of each constituent element of the semiconductor device 100 is described.

Each of the first metallic member 1, the second metallic member 2, the third metallic member 3, the first terminal 1a, the second terminal 2a, and the third terminal 3a contains a metal such as copper.

Each of the first electrode 11, the second electrode 12, and the third electrode 13 contains a metal such as aluminum.

Each of the n⁻ type semiconductor region 21, the p type semiconductor region 22, the n⁺ type semiconductor region 23, and the n⁺ type semiconductor region 24 contains, as a semiconductor material, silicon, silicon carbide, gallium nitride, or gallium arsenide. In a case where silicon is used as a semiconductor material, arsenic, phosphorus, or antimony can be used as an n type impurity. Boron can be used as a p type impurity in some embodiments.

The gate electrode 30 contains an electrical conducting material such as polysilicon. The electrical conducting material may have an impurity added thereto. The gate insulating layer 31 contains an insulating material such as silicon oxide.

Each of the connection portions 51 to 55 contains a metal such as tin, antimony, silver, or copper.

Advantageous effects of the embodiment are described.

When the semiconductor chip 10 enters an on-state, an electric current flows through the semiconductor layer SL. When an electric current flows through the semiconductor layer SL, heat is generated therein. The heat generated in the semiconductor layer SL is discharged from the first metallic member 1 and the second metallic member 2 via the first electrode 11 and the second electrode 12.

The semiconductor chip 10 includes a first portion 10a and a second portion 10b as illustrated in FIG. 4. The first portion 10a overlaps the second metallic member 2 as viewed in the Z-direction. Therefore, heat generated in the first portion 10a is likely to be discharged to the second metallic member 2. The second portion 10b does not overlap the second metallic member 2 as viewed in the Z-direction. Therefore, heat generated in the second portion 10b is unlikely to be discharged to the second metallic member 2 as compared with heat generated in the first portion 10a. When the semiconductor chip 10 operates, the temperature of the second portion 10b becomes higher than the temperature of the first portion 10a.

When the semiconductor chip 10 is turned on, an electric current begins to flow from the first electrode 11 to the second electrode 12. At this time, if an electric current excessively concentrates on some channels, breakage of the semiconductor chip 10 occurs. When the temperature of the second portion 10b is higher than the temperature of the first portion 10a, the electrical resistance of a semiconductor region in the second portion 10b is lower than the electrical resistance of a semiconductor region in the first portion 10a. Such a difference in electrical resistance causes an electric current to flow while concentrating on the second portion 10b when the semiconductor chip 10 is turned on. This may cause breakage of the semiconductor chip 10. Particularly, the area of the second portion 10b is smaller than the area of the first portion 10a as viewed in the Z-direction. Therefore, an electric current is likely to flow while concentrating on the second portion 10b.

In the semiconductor device 100 according to at least one embodiment, as illustrated in FIGS. 6A and 6B, the thickness T2 of the gate insulating layer 31 in the second portion 10b is larger than the thickness T1 of the gate insulating layer 31 in the first portion 10a. If the thickness T2 is larger than the thickness Tl, when a voltage is applied to the gate electrode 30, the strength of an electric field in a boundary portion between the p type semiconductor region 22 and the gate insulating layer 31 decreases. Even when the same voltage is applied to the gate electrode 30 in the first portion 10a and the gate electrode 30 in the second portion 10b, the width of a channel narrows in the second portion 10b or no channel is formed in the second portion 10b. Therefore, in the second portion 10b, the electrical resistance which occurs when the semiconductor chip 10 is in an on-state increases as compared with the first portion 10a. In other words, the gain of the gate electrode 30 in the second portion 10b is lower than the gain of the gate electrode 30 in the first portion 10a.

The electrical resistance of the second portion 10b, being increased, causes an electrical current to be unlikely to concentrate on the second portion 10b when the semiconductor chip 10 is turned on. For example, an electric current flows while diverging into the first portion 10a and the second portion 10b. Alternatively, an electric current mainly flows through the first portion 10a. The area of the first portion 10a is larger than the area of the second portion 10b. Therefore, even if an electric current flows mainly through the first portion 10a, the concentration of an electric current can be prevented or reduced as compared with a case where an electric current flows mainly through the second portion 10b. According to at least one embodiment, the probability of the semiconductor chip 10 being destroyed by concentration of an electrical current can be reduced.

Alternatively, in order to prevent or reduce concentration of an electrical current in the second portion 10b, a configuration in which the n⁺ type semiconductor region 23 or the gate electrode 30 is not provided in the second portion 10b is conceivable, thus preventing an electric current from flowing to the second portion 10b. In this configuration serving as a reference example, an electric current flows through only the first portion 10a. Accordingly, an on-resistance increases as compared with that in the semiconductor device 100. At least one embodiment therefore enables, while reducing the probability of destruction of the semiconductor chip 10 occurring, reducing the on-resistance of a semiconductor device as compared with the reference example.

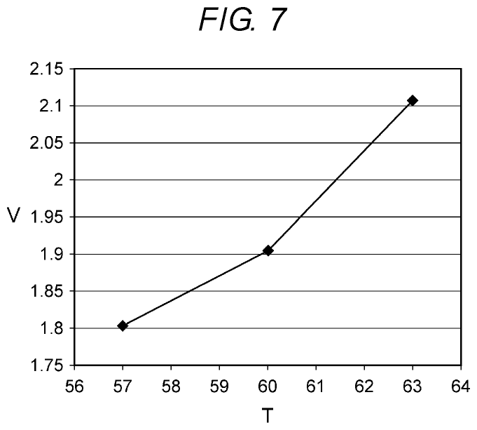

FIG. 7 is a graph illustrating a relationship between the thickness of a gate insulating layer and a threshold value for a voltage of a gate electrode. In FIG. 7, the horizontal axis indicates the thickness T of the gate insulating layer 31. The vertical axis indicates the voltage V of the gate electrode 30 which is required to form a channel in the p type semiconductor region 22. In other words, the vertical axis indicates a threshold value for the voltage.

As illustrated in FIG. 7, as the thickness of the gate insulating layer 31 becomes larger, the threshold value increases. As the thickness T2 becomes larger, an electrical current becomes more unlikely to concentrate on the second portion 10b. For example, if the threshold value of the gate electrode 30 in the second portion 10b is 0.05 V or higher than the threshold value of the gate electrode 30 in the first portion 10a, concentrating of an electrical current in the second portion 10b can effectively be prevented or reduced. On the other hand, if the thickness T2 is too large, the electrical resistance of the second portion 10b becomes excessively high, so that the on-resistance of the semiconductor device 100 increases. From these viewpoints, it is favorable that the thickness T2 is 1.01 times or more and 1.1 times or less the thickness T1. It is more favorable that the thickness T2 is 1.02 times or more and 1.05 times or less the thickness T1.

As illustrated in FIGS. 6A and 6B, the length L2 may be smaller than the length L1. If the length L2 is smaller than the length L1, the electrical resistance of the gate electrode 30 in the second portion 10b becomes higher than the electrical resistance of the gate electrode 30 in the first portion 10a. Accordingly, the gate resistance of a route including the second portion 10b becomes higher than the gate resistance of a route including the first portion 10a. At the time of a transient response obtained when a voltage is applied to the third electrode 13, a delay occurs in transferring a signal to the gate electrode 30 in the second portion 10b as compared with that in the first portion 10a. As a result, immediately after turning-on, an electric current becomes unlikely to flow to the second portion 10b. This enables further preventing or reducing of the concentration of an electric current in the second portion 10b at the time of turning-on and further reduces the probability of the semiconductor chip 10 being destroyed. 10 further increase the electrical resistance of the gate electrode 30 of the second portion 10b, as illustrated in FIGS. 6A and 6B, the length L4 may be smaller than the length L3. The impurity concentration in the gate electrode 30 of the second portion 10b maybe lower than the impurity concentration in the gate electrode 30 of the first portion 10a. Satisfying at least one of a relationship between the lengths L1 and L2, a relationship between the lengths L3 and L4, and a relationship between the impurity concentrations makes the electrical resistance of the gate electrode 30 of the second portion 10b higher than the electrical resistance of the gate electrode 30 of the first portion 10a.

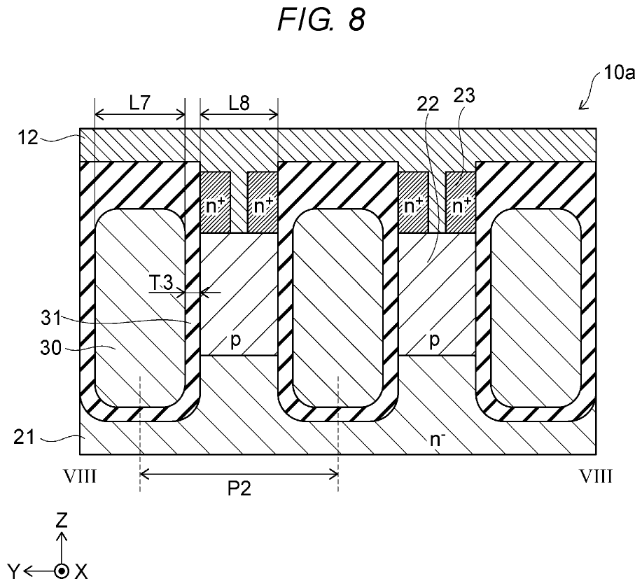

FIG. 8 is a sectional view taken along line VIII-VIII illustrated in FIG. 4. FIG. 8 illustrates another cross-section of the p type semiconductor region 22, the n⁺ type semiconductor region 23, and the gate electrode 30, which are illustrated in FIG. 6B.

More specifically, a part of the p type semiconductor region 22, a part of the n⁺ type semiconductor region 23, a part of the gate electrode 30, and a part of the gate insulating layer 31, which are illustrated in FIG. 6B and FIG. 8, are provided in the second portion 10b as illustrated in FIG. 6B. Another part of the p type semiconductor region 22, another part of the n⁺ type semiconductor region 23, another part of the gate electrode 30, and another part of the gate insulating layer 31 are provided in the first portion 10a as illustrated in FIG. 8.

The thickness T3 of the above-mentioned another part of the gate insulating layer 31 provided in the first portion 10a may be smaller than the thickness T2 of the above-mentioned part of the gate insulating layer 31 provided in the second portion 10b, as illustrated in FIG. 8. Making the thickness T3 smaller than the thickness T2 reduces the electrical resistance in a channel near the above-mentioned another part of the gate insulating layer 31. This enables, while reducing the probability of the semiconductor chip 10 being broken, reducing the on-resistance of the semiconductor device 100.

For example, as illustrated in FIG. 6B and FIG. 8, the length L7 of the above-mentioned another part of the gate electrode 30 as viewed in the Y-direction may be larger than the length L2 of the above-mentioned part of the gate electrode as viewed in the Y-direction. The length L8 of the above-mentioned another part of the p type semiconductor region 22 as viewed in the Y-direction may be larger than the length L6 of the above-mentioned part of the p type semiconductor region 22 as viewed in the Y-direction.

### Modification Examples

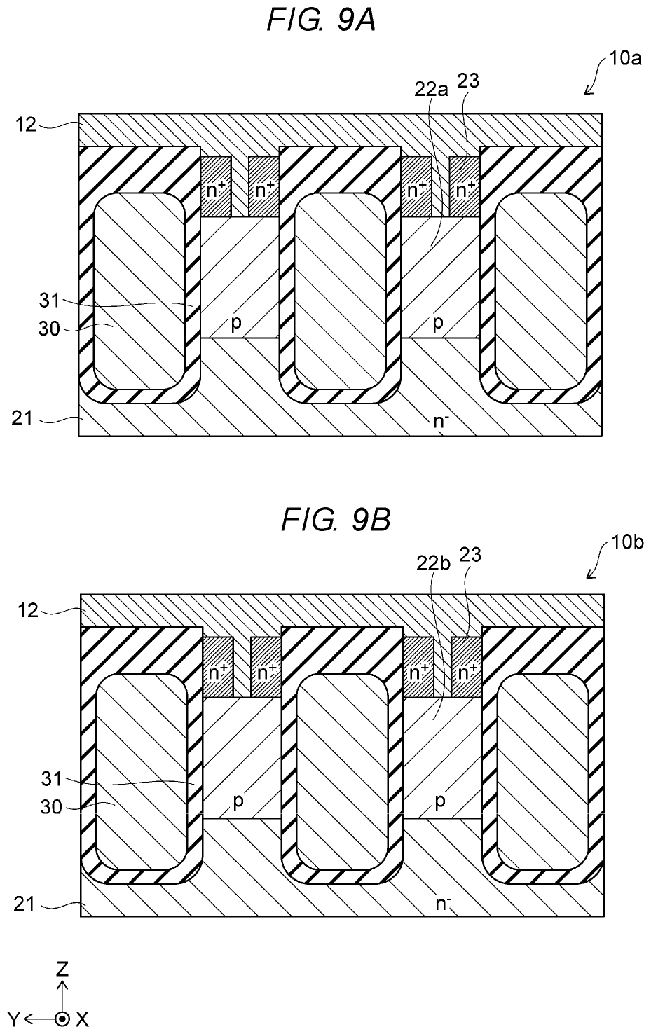

FIGS. 9A and 9B, FIGS. 10A and 10B, FIG. 11, FIG. 12, FIGS. 13A and 13B, and FIG. 14 are sectional views illustrating portions of semiconductor devices according to respective modification examples of the embodiment.

The p-type impurity concentration in the p type semiconductor region 22 of the second portion 10b may be made higher than the p-type impurity concentration in the p type semiconductor region 22 of the first portion 10a. For example, as illustrated in FIGS. 9A and 9B, a p type semiconductor region 22a is provided in the first portion 10a. A p type semiconductor region 22b which is higher in p-type impurity concentration than the p type semiconductor region 22a is provided in the second portion 10b. If the p-type impurity concentration in the p type semiconductor region 22 is high, when a voltage is applied to the gate electrode 30, the width of a channel becomes smaller or a channel does not form.

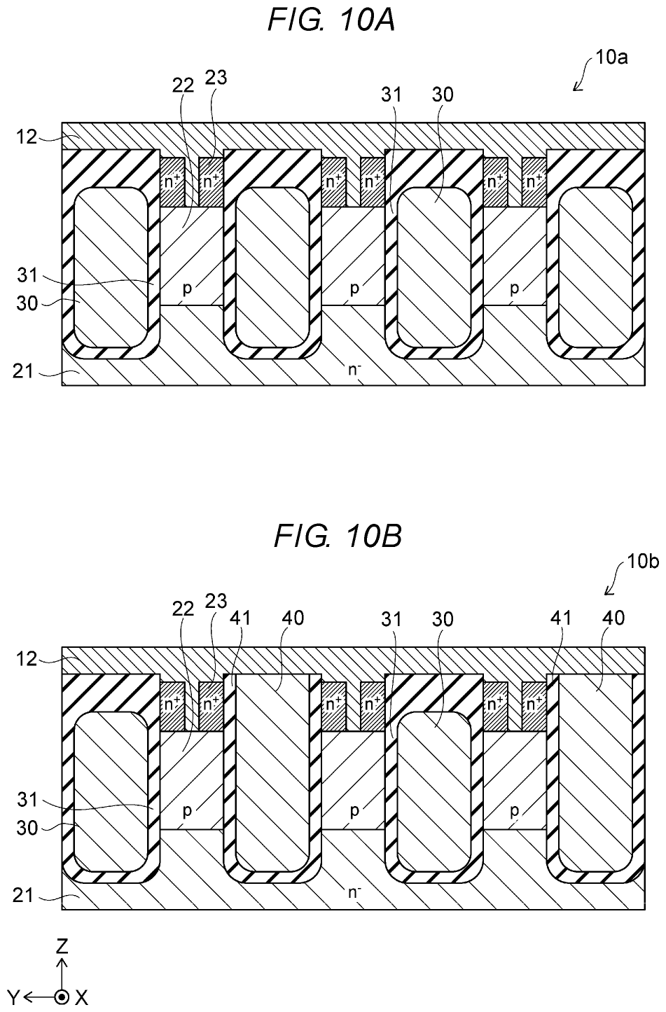

As illustrated in FIGS. 10A and 10B, in the second portion 10b, at least a part of a plurality of gate electrodes 30 may be replaced by conductive portions 40. In the illustrated example, in the second portion 10b, a part of a plurality of p type semiconductor regions 22 respectively faces a plurality of gate electrodes 30 via a plurality of gate insulating layers 31. In the second portion 10b, another part of the plurality of p type semiconductor regions 22 respectively faces a plurality of conductive portions 40 via a plurality of insulating layers 41.

The conductive portion 40 is electrically isolated from the gate electrode 30. For example, the conductive portion 40 is electrically connected to the second electrode 12. Alternatively, the electric potential of the conductive portion 40 may be a floating voltage. With the gate electrode 30 replaced by the conductive portion 40, the channel density of the second portion 10b becomes lower than the channel density of the first portion 10a. The ratio of the number of gate electrodes 30 to the number of conductive portions 40 in the second portion 10b is not limited to the illustrated example, but can be changed as appropriate.

According to at least any of the structure illustrated in FIGS. 9A and 9B and the structure illustrated in FIGS. 10A and 10B, the electrical resistance of the second portion 10b becomes higher than the electrical distance of the first portion 10a. In other words, the gain of the gate electrode 30 in the second portion 10b becomes lower than the gain of the gate electrode 30 in the first portion 10a. This reduces the probability of the semiconductor chip 10 being broken by the concentration of an electric current on the second portion 10b.

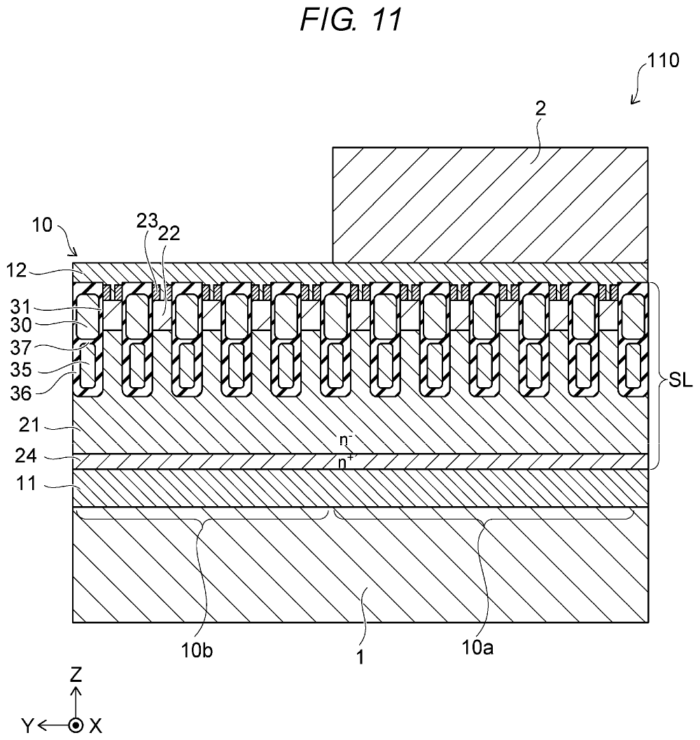

A semiconductor device 110 illustrated in FIG. 11 further includes conductive portions 35 in comparison with the semiconductor device 100. Each conductive portion 35 is provided within the n⁻ type semiconductor region 21 via an insulating layer 36. The gate electrode 30 is provided on the conductive portion 35 via an insulating layer 37. The conductive portion 35 is electrically isolated from the gate electrode 30 and is electrically connected to the second electrode 12. Alternatively, the conductive portion 35 may be electrically isolated from the second electrode 12 and may be electrically connected to the gate electrode 30.

When the semiconductor device 110 switches into an off-state, a positive voltage which is applied to the first electrode 11 with respect to the second electrode 12 increases. With an increase in the positive voltage, a depletion layer spreads from the interface between the n⁻ type semiconductor region 21 and the insulating layer 36 toward the n⁻ type semiconductor region 21. This spreading of the depletion layer enables increasing the breakdown voltage of the semiconductor device 110. Alternatively, increasing the n type impurity concentration in the n⁻ type semiconductor region 21 while maintaining the breakdown voltage of the semiconductor device 110 decreases the on-resistance of the semiconductor device 110.

When the on-resistance decreases, since the amount of heat generation also decreases, the current density of an electric current allowed to flow to the semiconductor device 110 can be increased. With the current density increased, when a temperature difference occurs between the first portion 10a and the second portion 10b, an electric current becomes further likely to concentrate on the second portion 10b. According to at least one embodiment, even in a case where the conductive portions 35 are provided, it is possible to effectively prevent or reduce the concentration of an electric current on the second portion 10b and to reduce the probability of destruction of the semiconductor chip 10 occurring.

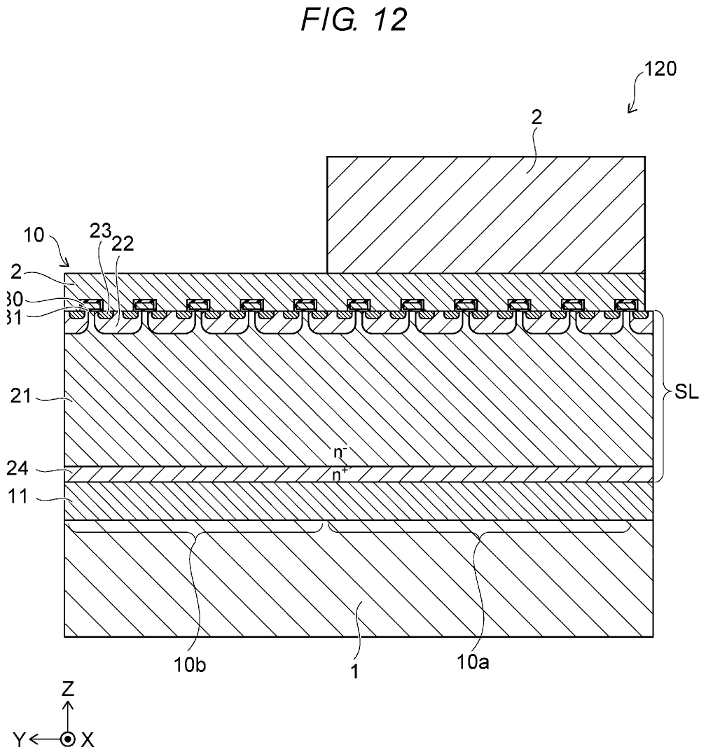

The semiconductor device 100 or 110 has a trench-type structure, in which the gate electrodes 30 are provided within the semiconductor layer SL. On the other hand, a semiconductor device 120 illustrated in FIG. 12 has a planer-type structure, in which the gate electrodes 30 are provided on the semiconductor layer SL. A plurality of gate electrodes 30 respectively faces a plurality of p type semiconductor regions 22 via a plurality of gate insulating layers 31 as viewed in the Z-direction.

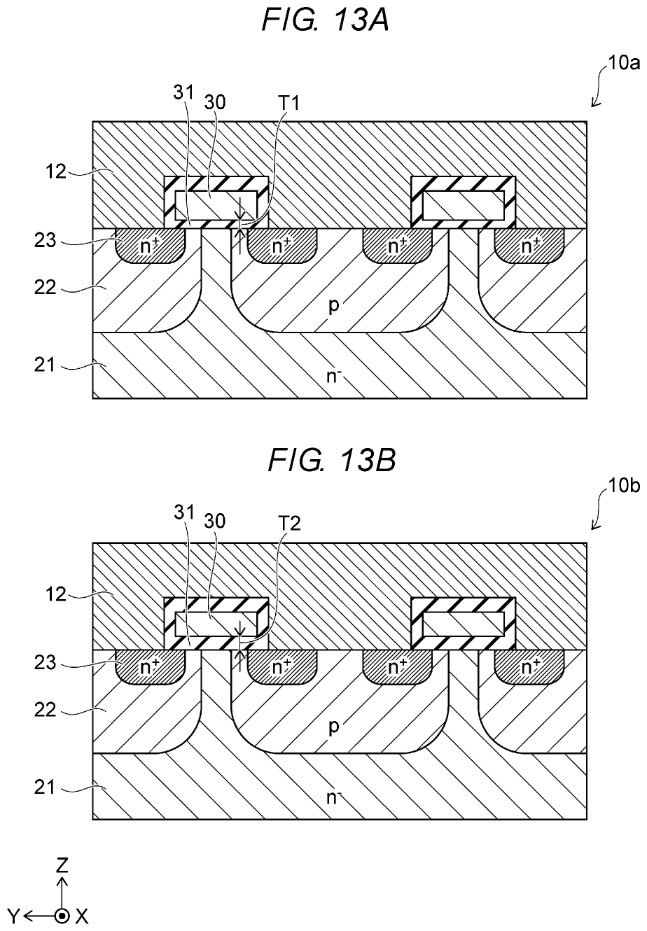

FIGS. 13A and 13B are sectional views illustrating respective portions illustrated in FIG. 12 in an enlarged manner. FIG. 13A illustrates a part of the first portion 10a. FIG. 13B illustrates a part of the second portion 10b.

Even in the semiconductor device 120, as illustrated in FIGS. 13A and 13B, the thickness T2 of the gate insulating layer 31 in the second portion 10b is larger than the thickness T1 of the gate insulating layer 31 in the first portion 10a. The thickness T1 corresponds to the length of the gate insulating layer 31 as viewed in the Z-direction between the p type semiconductor region 22 and the gate electrode 30 in the first portion 10a. The thickness T2 corresponds to the length of the gate insulating layer 31 as viewed in the Z-direction between the p type semiconductor region 22 and the gate electrode 30 in the second portion 10b.

Even in the planer-type gate structure, making the thickness T2 larger than the thickness T1 reduces the probability of the semiconductor chip 10 being destroyed by the concentration of an electric current on the second portion 10b.

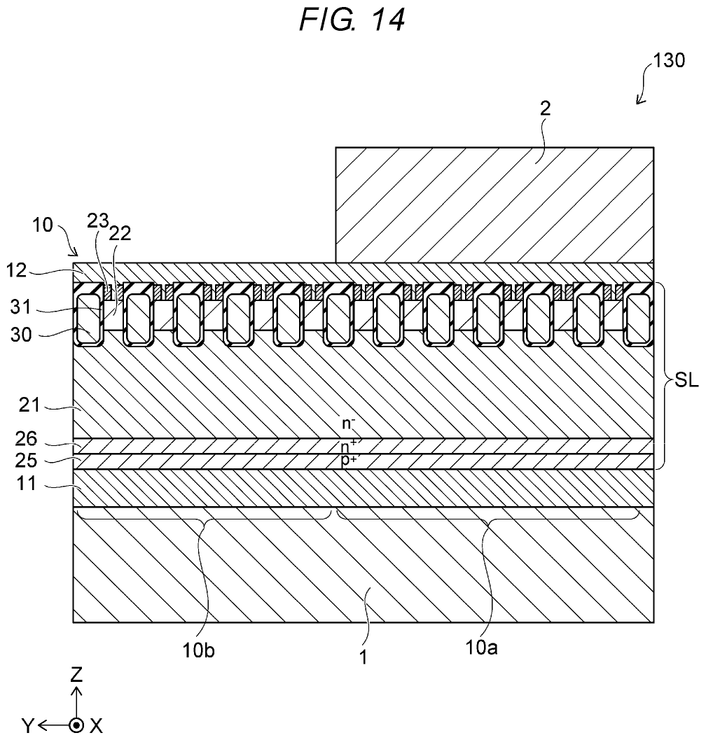

In each of the semiconductor devices 100, 110, and 120, the semiconductor chip 10 is a MOSFET. On the other hand, in a semiconductor device 130 illustrated in FIG. 14, the semiconductor chip 10 is an IGBT. The semiconductor chip 10 includes, instead of the n⁺ type semiconductor region 24, a p⁺ type semiconductor region 25 and an n type semiconductor region 26. The p⁺ type semiconductor region 25 is provided between the first electrode 11 and the n type semiconductor region 26, and is electrically connected to the first electrode 11. The n type semiconductor region 26 is provided between the p⁺ type semiconductor region 25 and the n⁻ type semiconductor region 21.

An operation of the semiconductor device 130 is described.

With a positive voltage being applied to the first electrode 11 with respect to the second electrode 12, a voltage higher than or equal to a threshold value is applied to the gate electrodes 30. With this application of the voltage, a channel (i.e., an inversion layer) is formed in each p type semiconductor region 22. Electrons are injected from the second electrode 12 to the n⁻ type semiconductor region 21 via the channel. Holes are injected from the p⁺ type semiconductor region 25 to the n⁻ type semiconductor region 21. This causes the semiconductor device 130 to enter an on-state. In the n⁻ type semiconductor region 21, conductivity modulation occurs due to the injected electrons and holes, so that the electrical resistance of the n⁻ type semiconductor region 21 decreases.

Even in the semiconductor device 130, using any of the above-mentioned methods to make the gain of the gate electrode 30 in the second portion 10b lower than the gain of the gate electrode 30 in the first portion 10a reduces the probability of the semiconductor chip 10 being destroyed by the concentration of an electric current on the second portion 10b.

Some or all of the structures described in the above-mentioned modification examples can be implemented in appropriate combination with each other. For example, in the semiconductor device 110, 120, or 130, as illustrated in FIGS. 9A and 9B, the p type impurity concentration in the p type semiconductor region 22 of the second portion 10b may be higher than the p type impurity concentration in the p type semiconductor region 22 of the first portion 10a. For example, in the semiconductor device 110, 120, or 130, as illustrated in FIGS. 10A and 10B, a part of a plurality of gate electrodes 30 in the second portion 10b may be replaced by the conductive portions 40.

In each of the above-described embodiments and modification examples, the relative highness or lowness in impurity concentration between respective semiconductor regions can be checked by using, for example, a scanning capacitance microscope (SCM). Furthermore, a carrier concentration in each semiconductor region can be deemed to be equal to an impurity concentration which is activated in each semiconductor region. Accordingly, the relative highness or lowness in carrier concentration between respective semiconductor regions can also be checked by using an SCM. Moreover, an impurity concentration in each semiconductor region may be measured by, for example, secondary ion mass spectrometry (SIMS).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first metallic member;
a first terminal electrically connected to the first metallic member;
a semiconductor chip disposed on the first metallic member and including:
a first electrode;
a first semiconductor region of a first conductive type disposed on the first electrode;
a plurality of second semiconductor regions of a second conductive type disposed on the first semiconductor region;
a plurality of third semiconductor regions of the first conductive type respectively disposed on the plurality of second semiconductor regions;
a plurality of gate insulating layers;
a plurality of gate electrodes respectively facing the plurality of second semiconductor regions via the plurality of gate insulating layers; and
a second electrode electrically connected to the plurality of second semiconductor regions and the plurality of third semiconductor regions;
a second terminal; and
a second metallic member disposed on the semiconductor chip, the second terminal being electrically connected to the second metallic member,
wherein the semiconductor chip includes:
a first portion located between the first metallic member and the second metallic member as viewed in a first direction from the first metallic member toward the second metallic member; and
a second portion located side by side with the first portion as viewed in a direction perpendicular to the first direction, and
wherein a thickness of each of the gate insulating layers in the second portion is larger than a thickness of each of the gate insulating layers in the first portion.

2. The semiconductor device according to claim 1, wherein the thickness of each of the gate insulating layers in the second portion is larger than between 1.01 and 1.1 times the thickness of each of the gate insulating layers in the first portion.

3. The semiconductor device according to claim 2, wherein the thickness of each of the gate insulating layers in the second portion is larger than between 1.02 and 1.05 times the thickness of each of the gate insulating layers in the first portion.

4. The semiconductor device according to claim 1, wherein an area of the first portion is greater than an area of the second portion.

5. The semiconductor device according to claim 1, wherein the second portion does not overlap the second metallic member as viewed in the first direction.

6. The semiconductor device according to claim 1, wherein a length of each of the gate electrodes, as viewed in a second direction perpendicular to the first direction, in the second portion is smaller than a length of each of the gate electrodes, as viewed in the second direction, in the first portion.

7. The semiconductor device according to claim 1, wherein a length of each of the gate electrodes, as viewed in the first direction, in the second portion is smaller than a length of each of the gate electrodes, as viewed in the first direction, in the first portion.

8. The semiconductor device according to claim 1, wherein a length of each of the second semiconductor regions, as viewed in a second direction perpendicular to the first direction, in the second portion is smaller than a length of each of the second semiconductor regions, as viewed in the second direction, in the first portion.

9. The semiconductor device according to claim 1, wherein a pitch of the plurality of gate electrodes in the second portion is equal to a pitch of the plurality of gate electrodes in the first portion.

10. A semiconductor device comprising:
a first metallic member;
a first terminal electrically connected to the first metallic member;
a semiconductor chip disposed on the first metallic member and including:
a first electrode;
a first semiconductor region of a first conductive type disposed on the first electrode;
a plurality of second semiconductor regions of a second conductive type disposed on the first semiconductor region;
a plurality of third semiconductor regions of the first conductive type respectively disposed on the plurality of second semiconductor regions;
a plurality of gate insulating layers;
a plurality of gate electrodes respectively facing the plurality of second semiconductor regions via the plurality of gate insulating layers; and
a second electrode electrically connected to the plurality of second semiconductor regions and the plurality of third semiconductor regions;
a second terminal; and
a second metallic member disposed on the semiconductor chip, the second terminal being electrically connected to the second metallic member,
wherein the semiconductor chip includes:
a first portion located between the first metallic member and the second metallic member as viewed in a first direction from the first metallic member toward the second metallic member; and
a second portion located side by side with the first portion as viewed in a direction perpendicular to the first direction, and
wherein an impurity concentration of the second conductive type of each of the second semiconductor regions in the second portion is higher than an impurity concentration of the second conductive type of each of the second semiconductor regions in the first portion.

11. A semiconductor device comprising:
a first metallic member;
a first terminal being electrically connected to the first metallic member;
a second metallic member disposed on the first metallic member;
a second terminal being electrically connected to the second metallic member; and
a semiconductor chip including:
a first portion located between the first metallic member and the second metallic member as viewed in a first direction from the first metallic member toward the second metallic member; and
a second portion located side by side with the first portion as viewed in a direction perpendicular to the first direction,
wherein the semiconductor chip includes:
a first electrode;
a first semiconductor region of a first conductive type disposed on the first electrode;
a plurality of second semiconductor regions of a second conductive type disposed on the first semiconductor region;
a plurality of third semiconductor regions of the first conductive type respectively disposed on the plurality of second semiconductor regions;
a plurality of gate insulating layers;
a plurality of gate electrodes provided in the first portion and the second portion and respectively facing a part of the plurality of second semiconductor regions via the plurality of gate insulating layers; and
a plurality of conductive portions provided in the second portion, respectively facing another part of the plurality of second semiconductor regions via a plurality of insulating layers, and electrically isolated from the plurality of gate electrodes.

12. A semiconductor device comprising:
a first metallic member;
a first terminal being electrically connected to the first metallic member;
a semiconductor chip disposed on the first metallic member and including:
a first electrode;
a first semiconductor region of a first conductive type disposed on the first electrode;
a plurality of second semiconductor regions of a second conductive type disposed on the first semiconductor region;
a plurality of third semiconductor regions of the first conductive type respectively disposed on the plurality of second semiconductor regions;
a plurality of gate insulating layers;
a plurality of gate electrodes respectively facing the plurality of second semiconductor regions via the plurality of gate insulating layers; and
a second electrode electrically connected to the plurality of second semiconductor regions and the plurality of third semiconductor regions;
a second terminal; and
a second metallic member disposed on the semiconductor chip, the second terminal being electrically connected to the second metallic member,
wherein the semiconductor chip includes:
a first portion located between the first metallic member and the second metallic member as viewed in a first direction from the first metallic member toward the second metallic member; and
a second portion located side by side with the first portion as viewed in a direction perpendicular to the first direction, and
wherein a gain of each of the gate electrodes provided in the second portion is lower than a gain of each of the gate electrodes disposed in the first portion.
